(19) United States
(12) Patent Application Publication
(10) Pub. No.: US 2023/0172005 A1
(43) Pub. Date: Jun. 1, 2023

(54) ORGANIC LIGHT-EMITTING DISPLAY DEVICE

(71) Applicant: SAMSUNG DISPLAY CO., LTD., Yongin-si (KR)

(72) Inventors: Heemin Park, Yongin-si (KR); Arong Kim, Yongin-si (KR); Jungsun Park, Yongin-si (KR); Yeonhwa Lee, Yongin-si (KR); Hyejin Gwark, Yongin-si (KR); Jaeik Kim, Yongin-si (KR); Joongu Lee, Yongin-si (KR); Kyuhwan Hwang, Yongin-si (KR)

(21) Appl. No.: 17/990,448

(22) Filed: Nov. 18, 2022

(30) Foreign Application Priority Data
Nov. 26, 2021 (KR) 10-2021-0166110

(51) Int. Cl. H01L 27/32

(52) U.S. Cl. CPC H01L 27/3246

(57) ABSTRACT

An organic light-emitting display device includes: a substrate; an insulating layer disposed on the substrate; a first electrode disposed on the insulating layer; a pixel defining layer disposed on the first electrode and defining an emission area by an opening that exposes at least part of the first electrode; a metal layer disposed on the pixel defining layer and in a non-emission area around the emission area; an organic light-emitting layer disposed on the first electrode in the opening; and a second electrode disposed on the organic light-emitting layer in the emission area and the non-emission area, where the metal layer is disposed between the pixel defining layer and the second electrode in the non-emission area.

This application claims priority to Korean Patent Application No. 10-2021-0166110, filed on Nov. 26, 2021, and all the benefits accruing therefrom under 35 U.S.C. § 119, the content of which in its entirety is herein incorporated by reference.

### BACKGROUND

### 1. Field

One or more embodiments relate to organic light-emitting display devices.

### 2. Description of the Related Art

An organic light-emitting diode includes two electrodes and a light-emitting layer located therebetween. As electrons injected from a cathode that is one electrode of the two electrodes are coupled to holes injected from an anode that is the other electrode of the two electrodes, excitons are formed in a light-emitting layer. As the excitons emit energy, light is emitted.

An organic light-emitting display device is a display device that implements an image by using the organic light-emitting diode. The organic light-emitting display device may include an insulating layer serving to planarize and insulate electrodes for forming electrodes and circuits connected to the organic light-emitting diode. As the configuration of the organic light-emitting display device becomes more complicated, a plurality of insulating layers is introduced.

### SUMMARY

One or more embodiments include an organic light-emitting display device capable of reducing a pixel shrinkage phenomenon. However, such an aspect is exemplary, and the scope of the present disclosure is not limited thereby.

Additional aspects will be set forth in part in the description which follows and, in part, will be apparent from the description, or may be learned by practice of the presented embodiments of the disclosure.

According to an aspect of the disclosure, an organic light-emitting display device includes: a substrate; an insulating layer disposed on the substrate; a first electrode disposed on the insulating layer; a pixel defining layer disposed on the first electrode and defining an emission area by an opening that exposes at least part of the first electrode; a metal layer disposed on the pixel defining layer and in a non-emission area around the emission area; an organic light-emitting layer disposed on the first electrode in the opening; and a second electrode disposed on the organic light-emitting layer in the emission area and the non-emission area. The metal layer is disposed between the pixel defining layer and the second electrode in the non-emission area.

The metal layer may be in direct contact with the pixel defining layer.

The organic light-emitting display device may further include a first functional layer disposed between the first electrode and the organic light-emitting layer in the opening of the pixel defining layer, where the first functional layer extends to an upper surface of the pixel defining layer, and the metal layer is disposed on the upper surface of the pixel defining layer and a side wall of the opening and between the pixel defining layer and the first functional layer.

The organic light-emitting display device may further include a second functional layer disposed between the organic light-emitting layer and the second electrode, where the metal layer is disposed between the second functional layer and the second electrode.

The organic light-emitting display device may further include a second functional layer disposed between the organic light-emitting layer and the second electrode, where the second functional layer includes a structure in which an electron transport layer and an electron injection layer are stacked, and the metal layer is disposed between the electron transport layer and the electron injection layer.

The organic light-emitting display device may further include a second functional layer disposed between the organic light-emitting layer and the second electrode, where the second functional layer includes a structure in which an electron transport layer and an electron injection layer are stacked, and the metal layer is disposed between the electron injection layer and the second electrode.

The insulating layer may include a first organic insulating layer and a second organic insulating layer.

The organic light-emitting display device may further include a conductive layer disposed between the first organic insulating layer and the second organic insulating layer.

The metal layer may include at least one selected from the group consisting of ytterbium (Yb) and magnesium (Mg).

The thickness of the metal layer may be about 19 angstroms (Å) to about 1000 Å.

The metal layer may have an octagonal shape in a plan view.

Furthermore, according to another aspect of the disclosure, an organic light-emitting display device includes: a substrate; a thin film transistor disposed on the substrate and including a semiconductor layer, a gate electrode, a source electrode, and a drain electrode; an insulating layer disposed on the thin film transistor, a first electrode disposed on the insulating layer; a pixel defining layer disposed on the first electrode and defining an emission area by an opening that exposes at least part of the first electrode; a metal layer disposed on the pixel defining layer and in a non-emission area around the emission area; an organic light-emitting layer disposed on the first electrode in the opening; and a second electrode disposed on the organic light-emitting layer and in the emission area and the non-emission area. The metal layer is disposed between the pixel defining layer and the second electrode in the non-emission area.

Other aspects, features, and advantages other than those described above will become apparent from the following drawings, claims, and detailed description of the disclosure

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display device according to an embodiment;

FIG. 2 is a schematic equivalent circuit diagram of any one pixel of a display panel according to an embodiment;

FIG. 3 is a cross-sectional view of an organic light-emitting display device according to an embodiment, taken along a line A-A′ of FIG. 1;

FIG. 4 is a cross-sectional view of an organic light-emitting display device according to another embodiment;

FIG. 5 is a cross-sectional view of an organic light-emitting display device according to another embodiment;

FIG. 6 is a cross-sectional view of an organic light-emitting display device according to another embodiment;

FIG. 7 is a cross-sectional view of an organic light-emitting display device according to another embodiment;

FIG. 8 is a cross-sectional view of an organic light-emitting display device according to another embodiment;

FIG. 9 is a plan view of an organic light-emitting display device according to an embodiment;

FIG. 10 is a plan view of an organic light-emitting display device according to an embodiment;

FIG. 11 is a plan view of an organic light-emitting display device according to an embodiment;

FIG. 12 is a graph showing a degree of oxidation of ytterbium (Yb) through X-ray photoelectron spectroscopy; and

FIGS. 13A and 13B are images showing a comparison result of a pixel shrinkage prevention effect according to the thickness of Yb.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

The effect and features of the present embodiments, and a method to achieve the same, will be clearer referring to the detailed descriptions below with the drawings. However, the present embodiments may be implemented in various forms, not by being limited to the embodiments presented below. Rather, these embodiments are provided so that this disclosure will be thorough and complete, and will fully convey the scope of the disclosure to one of ordinary skill in the art.

Shapes, sizes, ratios, angles, numbers, and the like in the drawings to describe embodiments are exemplary and are not limited to the illustrations of the drawings. Throughout the specification, like reference numerals denote like constituent element. In the description of the disclosure, certain detailed explanations of the related art are omitted when it is deemed that they may unnecessarily obscure the essence of the disclosure. Terms such as “including,” “having,” and “consist of” may be intended to indicate a plurality of components unless the terms are used with the term “ . . . only,” An expression used in the singular encompasses the expression of the plural, unless it has a clearly different meaning in the context.

In the case where a position relationship between two items is described with the terms “on . . . ,” “on the top of . . . ,” or the like, one or more items may be interposed therebetween unless the term “directly” is used in the expression.

Furthermore, a number, for example, first, second, and the like, used in the description of an embodiment is merely an identification sign to distinguish one constituent element from another constituent element. Accordingly, without departing from the right scope of the disclosure, a first constituent element may be referred to as a second constituent element, and vice versa.

Sizes of components in the drawings may be exaggerated or reduced for convenience of explanation, and the disclosure is not necessarily limited thereto. “About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Each of the features of various embodiments of the disclosure can be partially or wholly combined or assembled and technologically variously interlocked and driven, and each embodiment may be implemented independently or together in a related relationship.

Hereinafter, the disclosure will be described below in detail with reference to the accompanying drawings.

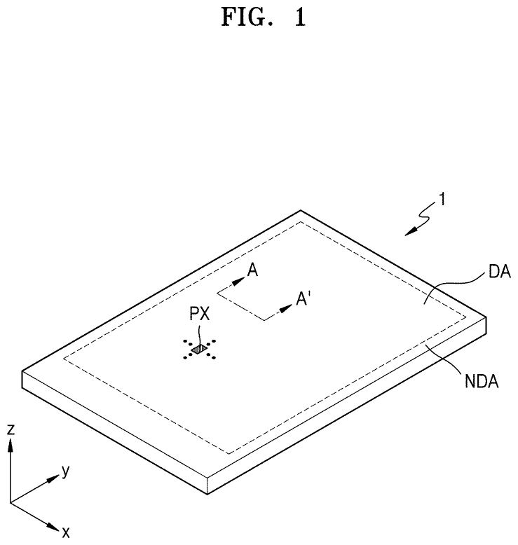

FIG. 1 is a schematic perspective view of an organic light-emitting display device 1 according to an embodiment.

Referring to FIG. 1, the organic light-emitting display device 1 may display an image. The organic light-emitting display device 1 may include a display area DA and a non-display area NDA. A plurality of pixels PX may be arranged in the display area DA. The non-display area NDA may at least partially surround the display area DA. The pixels PX may not be arranged in the non-display area NDA.

The organic light-emitting display device 1 may provide an image through an array of the pixels PX that are two-dimensionally arranged in the display area DA. Each of the pixels PX is an image unit capable of emitting light of a certain color, and the organic light-emitting display device 1 may provide an image by using the light emitted from the pixels PX.

The non-display area NDA, which is an area that does not provide an image, may surround the entirety of the display area DA. A driver or a main power line for providing electrical signals or power to pixel circuits may be arranged in the non-display area NDA. The non-display area NDA may include a pad that is an area to which electronic elements or a printed circuit board is electrically connected.

Although FIG. 1 illustrates the organic light-emitting display device 1 having a rectangular shape, in another embodiment, the organic light-emitting display device 1 may have various shapes, for example, circular, oval, polygonal such as triangular, or the like. Furthermore, although the organic light-emitting display device 1 has a flat shape in FIG. 1, the organic light-emitting display device 1 may be implemented in various forms such as a flexible, rollable, foldable display device, or the like in another embodiment.

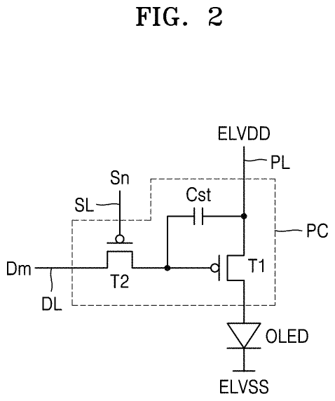

FIG. 2 is a schematic equivalent circuit diagram of a pixel circuit PC for driving any one organic light-emitting diode OLED of the organic light-emitting display device 1 according to an embodiment.

Referring to FIG. 2, each pixel circuit PC may be connected to the organic light-emitting diode OLED. The pixel circuit PC may include a driving thin film transistor T1, a switching thin film transistor T2, and a storage capacitor Cst.

The switching thin film transistor T2 is connected to a scan line SL and a data line DL, and may transmit, in response to a scan signal Sn input through the scan line SL, a data signal Dm input through the data line DL to the driving thin film transistor T1.

The storage capacitor Cst is connected to the switching thin film transistor T2 and a driving voltage line PL, and may store a voltage corresponding to a difference between a voltage received from the switching thin film transistor T2 and a first power voltage ELVDD supplied to the driving voltage line PL.

The driving thin film transistor T1 is connected to the driving voltage line PL and the storage capacitor Cst, and may control, in response to a voltage value stored in the storage capacitor Cst, a driving current flowing from the driving voltage line PL to the organic light-emitting diode OLED. The organic light-emitting diode OLED may emit light having a certain luminance by the driving current. A counter electrode, for example, a cathode, of the organic light-emitting diode OLED may receive a second power voltage ELVSS.

FIG. 2 illustrates that the pixel circuit PC includes two thin film transistors and one storage capacitor, but in another embodiment, the pixel circuit PC may include three or more thin film transistors.

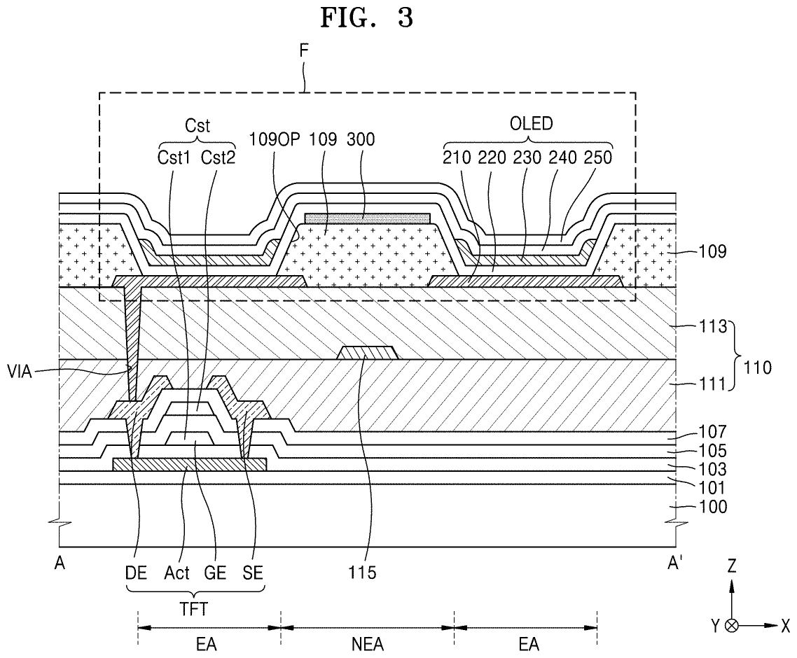

FIG. 3 is a schematic cross-sectional view of the organic light-emitting display device 1 of FIG. 1, taken along line A-A′ of FIG. 1.

Referring to FIG. 3, the organic light-emitting display device 1 according to an embodiment may include a substrate 100, an insulating layer 110, and a plurality of organic light-emitting diodes OLED disposed on the insulating layer 110. A metal layer 300 is disposed in a non-emission area NEA between the organic light-emitting diodes OLED.

In detail, the organic light-emitting display device 1 may include the substrate 100, the insulating layer 110 disposed above the substrate 100, a first electrode 210 disposed on the insulating layer 110, a pixel defining layer 109 disposed on the first electrode 210 and defining an emission area EA by an opening 1090P that exposes at least part of the first electrode 210, the metal layer 300 disposed on the pixel defining layer 109 in the non-emission area NEA around the emission area EA, an organic light-emitting layer 230 disposed above the first electrode 210 in the opening 1090P, and a second electrode 250 disposed above the organic light-emitting layer 230, the second electrode 250 being formed across the emission area EA and the non-emission area NEA.

In the present embodiment, the metal layer 300 may be disposed between the pixel defining layer 109 and the second electrode 250 in the non-emission area NEA.

The substrate 100 may include various materials such as glass, plastic, or metal. For example, the substrate 100 may include polymer resin such as polyethersulfone, polyarylate, polyetherimide, polyethylene naphthalate, polyethylene terephthalate, polyphenylene sulfide, polyimide, polycarbonate, cellulose triacetate, cellulose acetate propionate, or the like. In an embodiment, the substrate 100 may have a multilayer structure including a base layer including the above-described polymer resin and a barrier layer (not shown).

A buffer layer 101 may be disposed on the substrate 100. The buffer layer 101 may include an inorganic insulating material such as silicon nitride (SiYₓ), silicon oxynitride (SiOY), and silicon oxide (SiO₂), and may be a single layer or a multilayer including the above-described inorganic insulating material.

A thin film transistor TFT may be disposed on the substrate 100, and the thin film transistor TFT may be electrically connected to the first electrode 210. The thin film transistor TFT may include a semiconductor layer Act, a gate electrode GE insulated from the semiconductor layer Act, and a drain electrode DE and a source electrode SE electrically connected to the semiconductor layer Act.

The semiconductor layer Act may be disposed on the buffer layer 101. The semiconductor layer Act may include polysilicon, amorphous silicon, an oxide semiconductor, an organic semiconductor, or the like. The gate electrode GE is disposed above the semiconductor layer Act, and the source electrode SE and the drain electrode DE are electrically communicated in response to a signal applied to the gate electrode GE.

The gate electrode GE may include a low-resistance metal material. The gate electrode GE may include a conductive material including molybdenum (Mo), aluminum (Al), copper (Cu), titanium (Ti), or the like, and may be a multilayer or single layer including the above-described material.

A first gate insulating layer 103 may be disposed between the semiconductor layer Act and the gate electrode GE. The first gate insulating layer 103 may include an inorganic insulating material such as SiO₂, SiYₓ, SiOY, an aluminum oxide (Al₂O₃), a titanium oxide (TiO₂), a tantalum oxide (Ta₂O₅), a hafnium oxide (HfO₂), a zinc oxide (ZnOₓ), or the like. ZnOₓ may include a zinc oxide (ZnO) and/or a zinc peroxide (ZnO₂).

A second gate insulating layer 105 may cover the gate electrode GE. The second gate insulating layer 105, like the first gate insulating layer 103, may include an inorganic insulating material such as SiO₂, SiYₓ, SiOY, Al₂O₃, TiO₂, Ta₂O₅, HfO₂, ZnOₓ, or the like.

An upper electrode Cst2 of the storage capacitor Cst may be disposed above the second gate insulating layer 105. In an embodiment, the upper electrode Cst2 may overlap the gate electrode GE in a plan view. In this state, the gate electrode GE and the upper electrode Cst2 that overlap each other with the second gate insulating layer 105 therebetween may function as a lower electrode Cst1 and the upper electrode Cst2 of the storage capacitor Cst, respectively. As such, the storage capacitor Cst and the thin film transistor TFT may overlap each other in a plan view. In another embodiment, the storage capacitor Cst and the thin film transistor TFT. The upper electrode Cst2 may include Al, platinum (Pt), palladium (Pd), silver (Ag), magnesium (Mg), gold (Au), nickel (Yi), neodymium (Yd), iridium (Ir), chromium (Cr), Ca, Mo, Ti, tungsten (W), and/or Cu, and may be a single layer or a multilayer including the above-described material.

An interlayer-insulating layer 107 may cover the upper electrode Cst2. In an embodiment, the upper electrode Cst2 may overlap the gate electrode GE. The interlayer-insulating layer 107 may include SiO₂, SiYₓ, SiOY, Al₂O₃, TiO₂, Ta₂O₅, HfO₂, ZnOₓ, or the like. The interlayer-insulating layer 107 may be a single layer or a multilayer including the above-described inorganic insulating material.

The source electrode SE and the drain electrode DE may each be disposed on the interlayer-insulating layer 107. At least one of the source electrode SE and the drain electrode DE may include a material having excellent conductivity. At least one of the source electrode SE and the drain electrode DE may include a conductive material including Mo, Al, Cu, Ti, or the like, and may be provided as a multilayer or a single layer including the above-described material. In an embodiment, at least one of the source electrode SE and the drain electrode DE may have a multilayer structure of Ti/Al/Ti.

The insulating layer 110 may define a via-hole VIA therein through which any one of the source electrode SE and the drain electrode DE is exposed. The first electrode 210 is in contact with any one of the source electrode SE and the drain electrode DE through the via-hole VIA and is electrically connected to the thin film transistor TFT. In FIG. 3, as an example, the first electrode 210 is electrically connected to the drain electrode DE.

The insulating layer 110 may be disposed on the interlayer-insulating layer 107 covering the source electrode SE and the drain electrode DE. The insulating layer 110 may planarize its upper surface. A major upper surface plane may be defined by a first direction X and a second direction Y crossing the first direction X, and perpendicular to a thickness direction Z. The insulating layer 110 may be provided by stacking a first organic insulating layer 111 and a second organic insulating layer 113. The first organic insulating layer 111 and the second organic insulating layer 113 may include organic insulating materials, for example, general purpose polymers such as polymethylmethacrylate (“PMMA”) or polystyrene (“PS”), polymer derivatives having a phenolic group, acrylic polymers, imide-based polymers, arylether-based polymers, amide-based polymers, fluorine-based polymers, p-xylene-based polymers, vinyl alcohol-based polymers, or blends thereof. The first organic insulating layer 111 and the second organic insulating layer 113 may include the same material or different materials from each other.

A conductive layer 115 may be provided between the first organic insulating layer 111 and the second organic insulating layer 113. The conductive layer 115 may function as a wiring for transmitting various signals such as data signals and the like or a power voltage. Alternatively, the conductive layer 115 may function as a connection electrode for connecting the respective members. As the first organic insulating layer 111, the second organic insulating layer 113, and the conductive layer 115 therebetween are introduced, an organic light-emitting display device may be highly integrated.

The organic light-emitting diode OLED may be disposed on the insulating layer 110. The organic light-emitting diode OLED may include the first electrode 210, the organic light-emitting layer 230, and the second electrode 250. The organic light-emitting diode OLED may further include a first functional layer 220, and/or a second functional layer 240.

The first electrode 210 may be disposed on the insulating layer 110. The first electrode 210 may be electrically connected to the thin film transistor TFT through the via-hole VIA of the insulating layer 110. The first electrode 210 may include a conductive oxide such as an indium tin oxide (“ITO”), an indium zinc oxide (“IZO”), ZnO, an indium oxide (In₂O₃), an indium gallium oxide (“IGO”), or an aluminum zinc oxide (“AZO”). In another embodiment, the first electrode 210 may include a reflective film including Ag, Mg, Al, Pt, Pd, Au, Yi, Yd, Ir, Cr, or a compound thereof. In another embodiment, the first electrode 210 may further include a film including ITO, IZO, ZnO or In₂O₃ above/below the above-described reflective film. The disclosure is not limited thereto, and the first electrode 210 may include various materials, and may have a structure that is variously modifiable, for example, in a single layer or a multilayer.

The pixel defining layer 109 for defining the emission area EA by the opening 1090P that exposes at least part of the first electrode 210 may be disposed on the first electrode 210. The pixel defining layer 109 may include an organic insulating material and/or an inorganic insulating material. In some embodiments, the pixel defining layer 109 may include a light shielding material.

The organic light-emitting layer 230 may be disposed in the opening 1090P of the pixel defining layer 109. The organic light-emitting layer 230 may include various polymers or low molecular weight organic materials such as copper phthalocyanine (CuPc), Y,Y′-Di(naphthalene-1-yl)-Y,Y′-diphenyl-benzidine: YPB, tris-8-hydroxyquinoline aluminum (Alq₃), or the like.

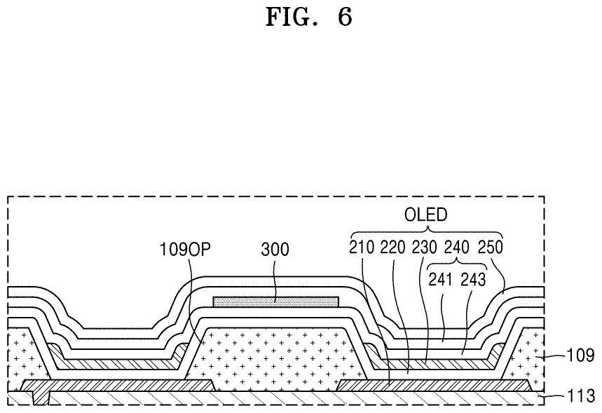

The first functional layer 220 and the second functional layer 240 may be disposed below and above the organic light-emitting layer 230, respectively. The first functional layer 220 may include, for example, a hole transport layer (“HTL”), or both the HTL and a hole injection layer (“HIL”). The second functional layer 240 is a constituent element disposed on the organic light-emitting layer 230, and may include an electron transport layer (“ETL”) and/or an electron injection layer (“EIL”) (See FIG. 6). The first functional layer 220 and/or the second functional layer 240 may be common layers to cover the entirety of the substrate 100, like the second electrode 250 that is to be described below.

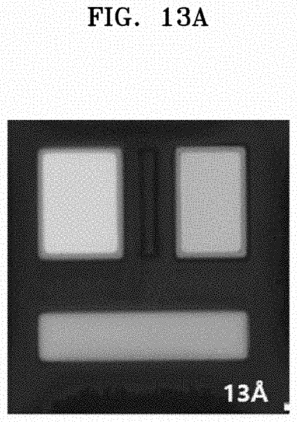

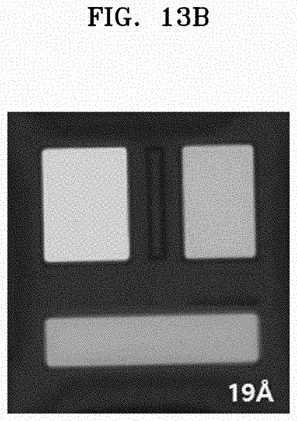

The metal layer 300 may be arranged in the non-emission area NEA. The metal layer 300 may be disposed between the pixel defining layer 109 and the second electrode 250 in the non-emission area NEA. In the insulating layer 110 including an organic material, outgassing of oxygen and/or moisture, or the like, may occur. In this case, the outgassed oxygen oxidizes the EIL and/or the cathode formed of metal, and thus, a pixel shrinkage phenomenon may occur. The pixel shrinkage phenomenon is that the active area of the pixel is reduced. (See the border of the pixel in FIG. 13A.)

In the present embodiment, the metal layer 300 serves to absorb outgassing occurring in the substrate 100, the insulating layer 110, the pixel defining layer 109, or the like, to thus reduce pixel shrinkage.

The metal layer 300 may include at least one of an alkali metal and an alkali earth metal. The metal layer 300 may include at least one of ytterbium (Yb), Ag, Mg, Al, lithium (Li), Ca, indium (In) and tin (Sn). In an embodiment, the metal layer 300 may include Yb or Mg. Yb and Mg are metals suitable for an oxygen trap, and may amplify a pixel shrinkage prevention effect.

In the present embodiment, the metal layer 300 may be formed in direct contact with an upper surface of the pixel defining layer 109. By directly contacting the pixel defining layer 109, moisture and a gas such as oxygen or the like outgassed from the pixel defining layer 109 may be efficiently absorbed.

The second electrode 250 may be disposed above the organic light-emitting layer 230 and the pixel defining layer 109. The second electrode 250 may include a conductive material having a low work function. For example, the second electrode 250 may include a (semi-)transparent layer including Ag, Mg, Al, Pt, Pd, Au, Yi, Yd, Ir, Cr, Li, Ca, an alloy thereof, or the like. Alternatively, the second electrode 250 may include a layer such as ITO, IZO, ZnO or In₂O₃ on a (semi-)transparent layer including the above-described material.

Although not illustrated, an encapsulation layer may be disposed above the organic light-emitting diode OLED to protect the organic light-emitting diode OLED.

The encapsulation layer may include at least one inorganic encapsulation layer and at least one organic encapsulation layer. In an embodiment, at least one inorganic encapsulation layer and at least one organic encapsulation layer may be alternately stacked. The inorganic encapsulation layer may include one or more inorganic materials of Al₂O₃, TiO₂, Ta₂O₅, ZnOₓ, SiO₂, SiYₓ, and SiOY. The organic encapsulation layer may include a polymer-based material. The polymer-based material may include acrylic resin, epoxy-based resin, polyimide, polyethylene, or the like. In an embodiment, the organic encapsulation layer may include acrylate.

In another embodiment, a sealing substrate (not shown) may be disposed above the organic light-emitting diode OLED. The sealing substrate may seal the organic light-emitting diode OLED with a sealing member arranged in the non-display area NDA.

A touch sensor layer may be disposed on the encapsulation layer or the sealing substrate. The touch sensor layer may obtain coordinates information according to an external input, for example, a touch event.

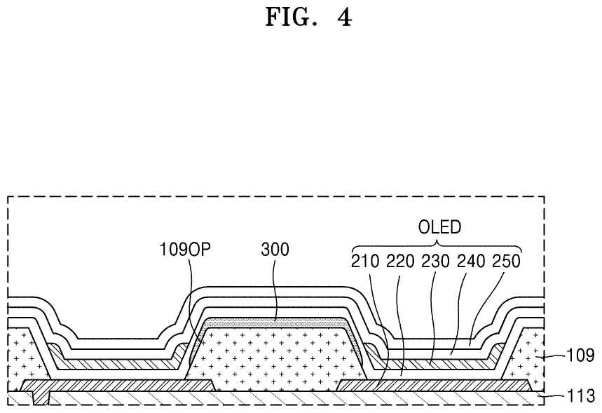

FIGS. 4 to 8 are cross-sectional views of organic light-emitting display devices according to some embodiments. In FIGS. 4 to 8 and FIG. 3, like reference numerals denote like constituent elements. FIGS. 4 to 8 illustrate modified embodiments of an F region of FIG. 3.

Referring to FIG. 4, the organic light-emitting display device 1 may include the substrate 100, the insulating layer 110, and the organic light-emitting diodes OLED disposed on the insulating layer 110, and the metal layer 300 is arranged in the non-emission area NEA between the organic light-emitting diodes OLED. The metal layer 300 may be provided in direct contact with the upper surface of the pixel defining layer 109.

In the present embodiment, the metal layer 300 may extend to the upper surface of the pixel defining layer 109 and a side wall of the opening 1090P. In this case, the metal layer 300 may be arranged apart from the first electrode 210. As the metal layer 300 is arranged to the side wall of the opening 1090P of the pixel defining layer 109, the metal layer 300 may absorb moisture or a gas such as oxygen or the like outgassed through the opening 1090P, and thus, the pixel shrinkage prevention effect may be further amplified.

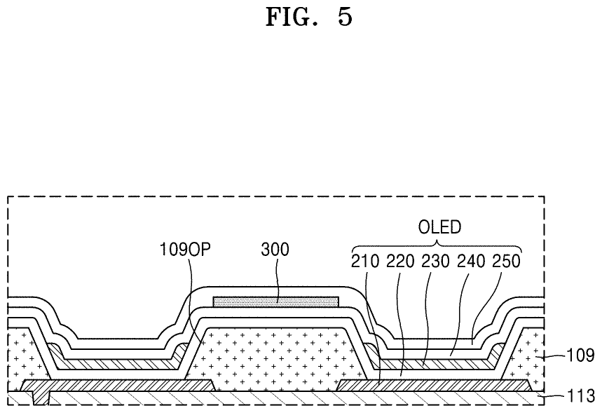

Referring to FIG. 5, the metal layer 300 may be arranged between the second functional layer 240 and the second electrode 250. The metal layer 300 may be arranged in direct contact with the second functional layer 240. As the metal layer 300 is arranged on an upper surface of the second functional layer 240, the metal layer 300 may absorb moisture or a gas such as oxygen or the like outgassed through the insulating layer 110, the pixel defining layer 109, and the second functional layer 240.

Referring to FIG. 6, the second functional layer 240 may include an ETL 243 and an EIL 241. The ETL 243 may be arranged on an upper surface of the organic light-emitting layer 230, and the EIL 241 may be arranged on an upper surface of the ETL 243.

In the present embodiment, the metal layer 300 may be arranged between the ETL 243 and the EIL 241. The metal layer 300 may absorb moisture or a gas such as oxygen or the like outgassed through the insulating layer 110 and the pixel defining layer 109.

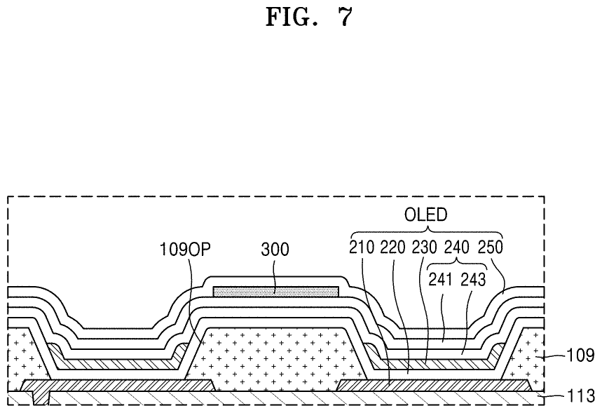

Referring to FIG. 7, the metal layer 300 may be arranged between the EIL 241 and the second electrode 250. The metal layer 300 is in direct contact with the second electrode 250, and may reduce the resistance of the second electrode 250.

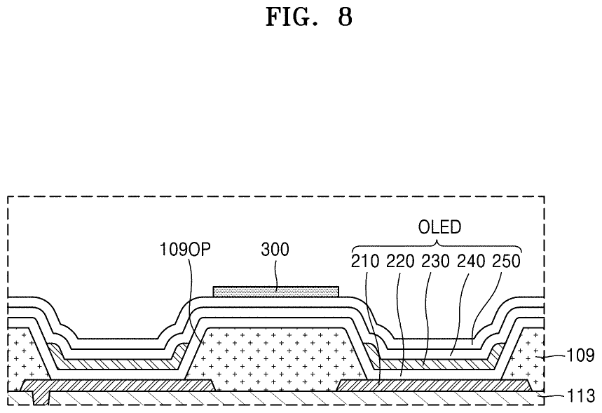

Referring to FIG. 8, the metal layer 300 may be disposed on the second electrode 250. The metal layer 300 is in direct contact with the second electrode 250, and may reduce the resistance of the second electrode 250. The metal layer 300 may absorb moisture or a gas such as oxygen or the like outgassed through the insulating layer 110 and the pixel defining layer 109.

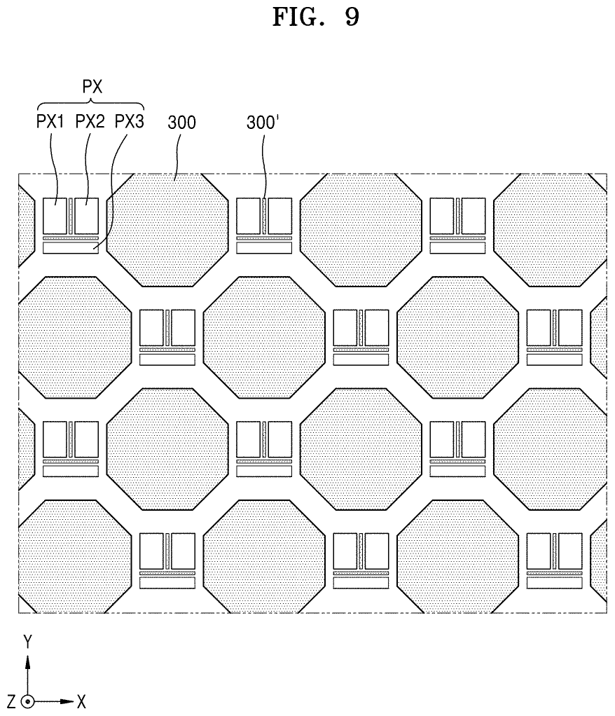

FIGS. 9 to 11 are plan views of organic light-emitting display devices according to some embodiments. As used herein, the “plan view” is a view from a thickness direction Z of the substrate 100.

Referring to FIGS. 9 to 11, a pixel PX may include a plurality of sub-pixels. The pixel PX may display an image by emitting light, and may include a first sub-pixel PX1, a second sub-pixel PX2, and a third sub-pixel PX3. The first sub-pixel PX1, the second sub-pixel PX2, and the third sub-pixel PX3 may emit red light, green light, and blue light, respectively. In another embodiment, the first sub-pixel PX1, the second sub-pixel PX2, and the third sub-pixel PX3 may emit red light, green light, blue light, or white light.

Referring to FIG. 9, the metal layer 300 may be arranged between the pixels PX. The metal layer 300 may have an octagonal shape in a plan view. In this case, as the metal layer 300 may be arranged close to the pixel PX and not overlapping the pixel PX, the pixel shrinkage prevention effect may be further amplified. The size of an octagonal shape of the metal layer 300 may be greater than a size of one pixel PX in the plan view. Although not illustrated, in another embodiment, the one octagonal shape of the metal layer 300 may be smaller than one pixel PX. In this case, a plurality of the shapes of metal layers that can be arranged close to one pixel PX may be provided.

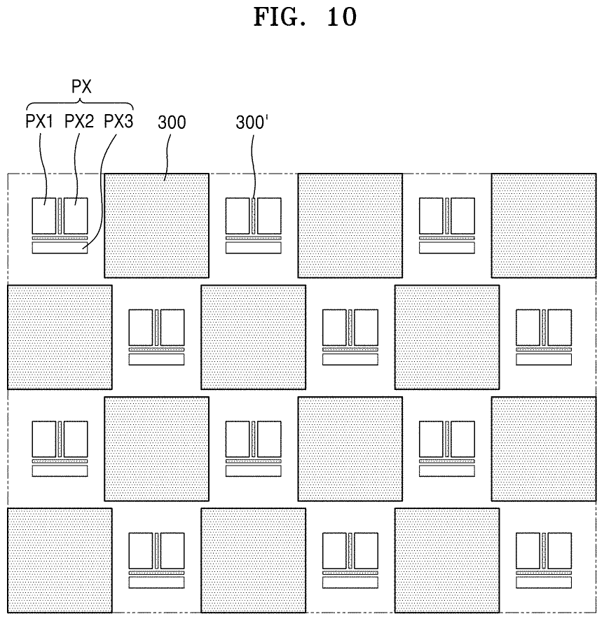

Although FIG. 9 illustrates that the shape in a plan view of the metal layer 300 is octagonal, referring to FIG. 10, the shape of the metal layer 300 may be variously modified, for example, in a rectangular shape or the like. In another embodiment, for example, the shape of the metal layer 300 may be any one of circular, oval, and polygonal.

An additional metal layer 300′ may be provided between sub-pixels included in one pixel PX. For example, the additional metal layer 300′ may be arranged between the first sub-pixel PX1 and the second sub-pixel PX2, the first sub-pixel PX1 and the third sub-pixel PX3, and the second sub-pixel PX2 and the third sub-pixel PX3, which neighbor each other. The additional metal layer 300′ may be arranged apart from the metal layer 300. The area of the additional metal layer 300′ may be smaller than the area of the metal layer 300.

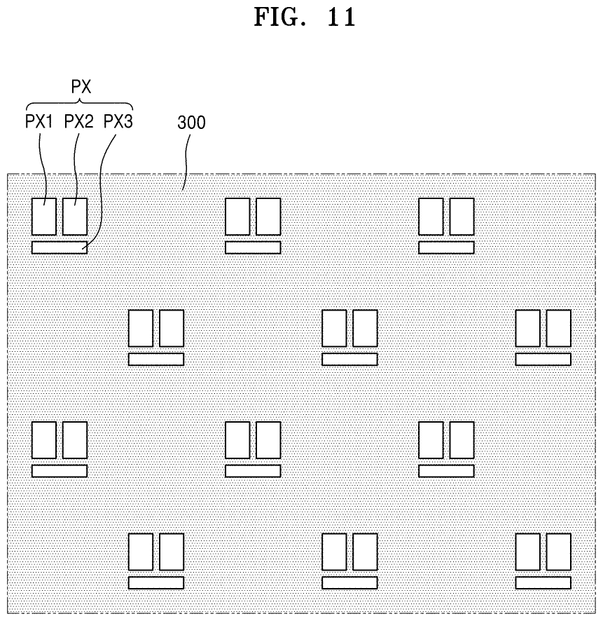

Referring to FIG. 11, the metal layer 300 may be seamlessly arranged in an area where the pixels PX is not arranged. The metal layer 300 may be greater in size than the pixel PX, and thus the amount of the outgassed moisture or a gas such as oxygen or the like to be absorbed by the metal layer 300 increases so that the pixel shrinkage prevention effect may be further amplified.

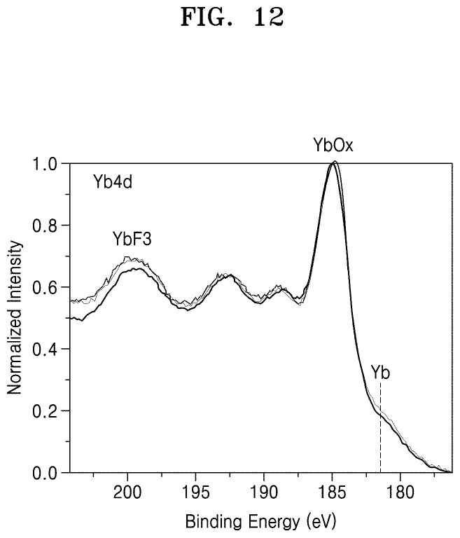

FIG. 12 is a graph showing a degree of oxidation of Yb through X-ray photoelectron spectroscopy, with respect to the Yb to be used as the metal layer 300.

Referring to FIG. 12, it may be seen that the amount of Yb present in a Yb—O state by being combined with oxygen is larger than the amount of Yb present by itself. In other words, the Yb is easy to be combined with oxygen after deposited in an organic light-emitting diode OLED process, and thus, it may be seen that pixel shrinkage is reduced as the Yb absorbs the outgassed oxygen.

FIGS. 13A and 13B are images showing a comparison result of a pixel shrinkage prevention effect according to the thicknesses of Yb to be used as the metal layer 300.

Referring to FIGS. 13A and 13B, it may be seen that, while the pixel shrinkage occurred when Yb having a thickness of 13 angstroms (Å) is deposited as the metal layer, no pixel shrinkage occurred when Yb having a thickness of 19 Å is deposited as the metal layer. This means that, when Yb is deposited to a thickness of 19 Å or more, Yb that is relatively thick may block most of outgassing components so that no pixel shrinkage occurs. However, when the thickness of the metal layer 300 exceeds 1000 Å, a step may be generated at portions where no metal layer is arranged. The thickness of the metal layer 300 is measured in the thickness direction Z of the substrate 100.

As described above, according to an organic light-emitting display device according to one or more embodiments, pixel shrinkage may be reduced from outgassing that may be generated from the insulating layer or the entire backplane without a reduction of panel efficiency by depositing the metal layer not in the emission area but in the non-emission area. The scope of the disclosure is not limited by the effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An organic light-emitting display device comprising:
a substrate;
an insulating layer disposed on the substrate;
a first electrode disposed on the insulating layer;
a pixel defining layer disposed on the first electrode and defining an emission area by an opening exposing at least part of the first electrode;
a metal layer disposed on the pixel defining layer and in a non-emission area around the emission area;
an organic light-emitting layer disposed on the first electrode in the opening; and
a second electrode disposed on the organic light-emitting layer in the emission area and the non-emission area,
wherein the metal layer is disposed between the pixel defining layer and the second electrode in the non-emission area.

2. The organic light-emitting display device of claim 1, wherein the metal layer is in direct contact with the pixel defining layer.

3. The organic light-emitting display device of claim 1, further comprising a first functional layer disposed between the first electrode and the organic light-emitting layer in the opening of the pixel defining layer,
wherein the first functional layer extends to an upper surface of the pixel defining layer, and
the metal layer is disposed on the upper surface of the pixel defining layer and a side wall of the opening and between the pixel defining layer and the first functional layer.

4. The organic light-emitting display device of claim 1, further comprising a second functional layer disposed between the organic light-emitting layer and the second electrode,
wherein the metal layer is disposed between the second functional layer and the second electrode.

5. The organic light-emitting display device of claim 1, further comprising a second functional layer disposed between the organic light-emitting layer and the second electrode,
wherein the second functional layer comprises a structure in which an electron transport layer and an electron injection layer are stacked, and
the metal layer is disposed between the electron transport layer and the electron injection layer.

6. The organic light-emitting display device of claim 1, further comprising a second functional layer disposed between the organic light-emitting layer and the second electrode,
wherein the second functional layer comprises a structure in which an electron transport layer and an electron injection layer are stacked, and
the metal layer is disposed between the electron injection layer and the second electrode.

7. The organic light-emitting display device of claim 1, wherein the insulating layer comprises a first organic insulating layer and a second organic insulating layer.

8. The organic light-emitting display device of claim 7, further comprising a conductive layer disposed between the first organic insulating layer and the second organic insulating layer.

9. The organic light-emitting display device of claim 1, wherein the metal layer comprises at least one selected from the group consisting of ytterbium (Yb) and magnesium (Mg).

10. The organic light-emitting display device of claim 1, wherein a thickness of the metal layer is about 19 angstroms (Å) to about 1000 Å.

11. The organic light-emitting display device of claim 1, wherein the metal layer has an octagonal shape in a plan view.

12. An organic light-emitting display device comprising:
a substrate;
a thin film transistor disposed on the substrate and comprising a semiconductor layer, a gate electrode, a source electrode, and a drain electrode;
an insulating layer disposed on the thin film transistor;
a first electrode disposed on the insulating layer;
a pixel defining layer disposed on the first electrode and defining an emission area by an opening exposing at least part of the first electrode;
a metal layer disposed on the pixel defining layer and in a non-emission area around the emission area;
an organic light-emitting layer disposed on the first electrode in the opening; and
a second electrode disposed on the organic light-emitting layer in the emission area and the non-emission area,
wherein the metal layer is disposed between the pixel defining layer and the second electrode in the non-emission area.

13. The organic light-emitting display device of claim 12, wherein the metal layer is in direct contact with the pixel defining layer.

14. The organic light-emitting display device of claim 12, further comprising a first functional layer disposed between the first electrode and the organic light-emitting layer in the opening of the pixel defining layer,
wherein the first functional layer extends to an upper surface of the pixel defining layer, and
the metal layer is disposed on the upper surface of the pixel defining layer and a side wall of the opening and between the pixel defining layer and the first functional layer.

15. The organic light-emitting display device of claim 12, further comprising a second functional layer disposed between the organic light-emitting layer and the second electrode,
wherein the metal layer is disposed between the second functional layer and the second electrode.

16. The organic light-emitting display device of claim 12, further comprising a second functional layer disposed between the organic light-emitting layer and the second electrode,
wherein the second functional layer has a structure in which an electron transport layer and an electron injection layer are stacked, and
the metal layer is disposed between the electron transport layer and the electron injection layer.

17. The organic light-emitting display device of claim 12, further comprising a second functional layer disposed between the organic light-emitting layer and the second electrode,
wherein the second functional layer has a structure in which an electron transport layer and an electron injection layer are stacked, and
the metal layer is disposed between the electron injection layer and the second electrode.

18. The organic light-emitting display device of claim 12, wherein the insulating layer comprises a first organic insulating layer and a second organic insulating layer.

19. The organic light-emitting display device of claim 12, wherein the metal layer comprises at least one selected from the group consisting of ytterbium (Yb) and magnesium (Mg).

20. The organic light-emitting display device of claim 12, wherein a thickness of the metal layer is about 19 Å to about 1000 Å.
